(19) United States
(12) Patent Application Publication
(10) Pub. No.: US 2025/0107453 A1
(43) Pub. Date: Mar. 27, 2025

(54) ORDERED ALLOY MAGNETIC TUNNEL JUNCTION DEVICE

(71) Applicant: INTERNATIONAL BUSINESS MACHINES CORPORATION, Armonk, NY (US)

(72) Inventors: Guohan Hu, Yorktown Heights, NY (US); Matthias Georg Gottwald, Ridgefield, CT (US); Alexander Reznicek, Troy, NY (US); Gukcheon Kim, Dobbs Ferry, NY (US)

(21) Appl. No.: 18/371,175

(22) Filed: Sep. 21, 2023

(51) Int. Cl. H10N 50/80; H10B 61/00; H10N 50/01; H10N 50/20; H10N 50/85

(52) U.S. Cl. CPC H10N 50/80; H10B 61/00; H10N 50/01; H10N 50/20; H10N 50/85

(57) ABSTRACT

A magnetic tunnel junction device is provided. The magnetic tunnel junction device includes a seed layer, and a free layer structure on the seed layer. The free layer structure includes a first free layer, a spacer layer formed on the first free layer, and a second free layer formed on the spacer layer. The first and second free layers each include an ordered magnetic alloy.

### BACKGROUND

The present disclosure relates generally to the electrical, electronic and computer arts and, more particularly, to magnetic tunnel junction (MTJ) pillars.

Magnetic tunnel junction stacks are suitable for use in various electronic applications, including non-volatile memory devices and magnetic field sensors. Magnetic random access memory (MRAM) can, for example, offer faster operational speed than flash memory. MRAM devices may be able to replace dynamic random access memory (DRAM) devices in some applications.

In general, magnetic tunnel junctions include two magnetic layers and a tunnel barrier layer positioned between the magnetic layers. The magnetic layers can be characterized as “reference” and “free” layers, respectively while the tunnel barrier can be a thin tunneling oxide layer. The magnetization direction of one layer of the junction is fixed so that it serves as the reference layer. The magnetization of the free layer can be determined by an electrical input. A MTJ includes two stable resistance states. Charge current from the reference layer to the free layer causes the MTJ to switch between states by overcoming the energy barrier.

Fabrication of MTJ pillars with ordered alloy free layers has typically required forming a thick multilayer seed layer stack comprising, for example, MnN and CoAl having a combined thickness of about five hundred Angstroms. Alternatively, a relatively thick multilayer seed layer stack may comprise ScN, Cr, IrAl, and CoAl. A free layer, a tunnel barrier, and a reference layer are formed over the seed layer. Crystalline MgO tunnel barriers grown on amorphous layers can obtain an oriented (100) texture and provide a relatively high TMR (tunneling magnetoresistance) ratio. In general, texture is the distribution of crystallographic orientations of a polycrystalline sample. A sample in which these orientations are fully random is said to have no distinct texture. If the crystallographic orientations are not random, but have some preferred orientation, then the sample has a weak, moderate or strong texture. The degree is dependent on the percentage of crystals having the preferred orientation. When using a spin-torque-transfer (STT) MTJ, the difference in the tunneling current, as the spin alignment of the free and pinned layers is switched between being parallel (P) and anti-parallel (AP), is known as a tunnel magneto-resistance (TMR) ratio.

CoFeB based MTJ pillars fundamentally have a high current penalty for reduced write times with respect to longer write pulses like 30 or 100 ns, especially below 10 ns. MTJ devices with ordered alloy free layers can have less relative current penalty for reducing the write time.

### SUMMARY

Embodiments of the present disclosure relate to a magnetic tunnel junction device including a seed layer, and a free layer structure on the seed layer. The free layer structure includes a first free layer, a spacer layer formed on the first free layer, and a second free layer formed on the spacer layer. The first and second free layers each include an ordered magnetic alloy.

In certain embodiments, an MRAM storage device is provided. The MRAM storage device includes a magnetic tunnel junction device including a seed layer, and a free layer structure on the seed layer. The free layer structure includes a first free layer, a spacer layer formed on the first free layer, and a second free layer formed on the spacer layer. The first and second free layers each include an ordered magnetic alloy.

The above summary is not intended to describe each illustrated embodiment or every implementation of the present disclosure.

### BRIEF DESCRIPTION OF THE DRAWINGS

The drawings included in the present application are incorporated into, and form part of, the specification. They illustrate embodiments of the present disclosure and, along with the description, explain the principles of the disclosure. The drawings are only illustrative of certain embodiments and do not limit the disclosure.

FIG. 1 is a cross-sectional view of an MTJ device at an intermediate stage of the manufacturing process, according to embodiments.

FIG. 2 depicts a cross-sectional view of the MTJ device of FIG. 1 after additional fabrication operations, according to embodiments.

FIG. 3 depicts a cross-sectional view of the MTJ device of FIG. 2 after additional fabrication operations, according to embodiments.

FIG. 4 depicts a cross-sectional view of the MTJ device of FIG. 3 after additional fabrication operations, according to embodiments.

FIG. 5 depicts a cross-sectional view of the MTJ device of FIG. 4 after additional fabrication operations, according to embodiments.

FIG. 6 depicts a cross-sectional view of the MTJ device of FIG. 5 after additional fabrication operations, according to embodiments.

FIG. 7 depicts a cross-sectional view of the MTJ device of FIG. 6 after additional fabrication operations, according to embodiments.

FIG. 8 depicts a cross-sectional view of the MTJ device of FIG. 7 after additional fabrication operations, according to embodiments.

FIG. 9 depicts a cross-sectional view of the MTJ device of FIG. 8 after additional fabrication operations, according to embodiments.

### DETAILED DESCRIPTION

The present disclosure describes MTJ devices and methods of manufacturing MRAM devices. In particular, the present disclosure describes MTJ devices and MRAM storage devices including an MTJ pillar having an ordered alloy material as free layer. In general, an ordered alloys are alloys composed of at least two types of atoms, which alternate in position with some regularity. The MTJ pillar includes a multilayer free layer that includes an ordered magnetic alloy that is a Heusler alloy. Multiples layers of the Huesler compound free layer are separated by a spacer layer.

A memory device has a critical voltage (Vc) for a given write pulse length which is the voltage needed to have a 50% success rate of switching between the 0 and 1 state or from 1 to 0. In general, the critical voltage Vc increases with decreasing pulse width. For a given MRAM memory device the probability to unsuccessfully write the magnetization for a given write pulse length and voltage is the so-called write error rate (WER). The ratio of the voltage needed to write a device with a certain WER for a given pulse width divided by the voltage Vc for the same pulse width is defined as overdrive. The lower the overdrive for a given write time and WER goal the less additional voltage is needed to make the device operation more reliable. In general, overdrive as the Vc are pulse width dependent. For shorter write pulses both Vc and overdrive for a given WER increase. Therefore, shortening the write pulse duration for a given WER has a double penalty: Vc and overdrive increase with shorter pulse width. The penalty for Vc increase and overdrive increase is free layer dependent. Minimizing Vc penalty and overdrive penalty for a given WER is needed to enable reliable high speed writing of MRAM devices. Further, to keep power consumption low a combination of low critical write voltage Vc, low overdrive and low write current Ic (pw,WER) is needed. Ic (pw,WER), overdrive and Vc increase with shorter pulse width are free layer materials dependent.

Free layers made from ordered alloys may have lower overdrive and Vc increase for shorter write pulse widths effectively lowering Ic (pw,WER) with respect to a free layer material that has more pulse width dependent penalties at shorter write times. For faster and more reliable memory applications further lowering of overdrive, Vc and Ic (pw,WER) is needed.

Various embodiments of the present disclosure are described herein with reference to the related drawings. Alternative embodiments can be devised without departing from the scope of the present disclosure. It is noted that various connections and positional relationships (e.g., over, below, adjacent, etc.) are set forth between elements in the following description and in the drawings. These connections and/or positional relationships, unless specified otherwise, can be direct or indirect, and the present disclosure is not intended to be limiting in this respect. Accordingly, a coupling of entities can refer to either a direct or an indirect coupling, and a positional relationship between entities can be a direct or indirect positional relationship. As an example of an indirect positional relationship, references in the present description to forming layer “A” over layer “B” include situations in which one or more intermediate layers (e.g., layer “C”) is between layer “A” and layer “B” as long as the relevant characteristics and functionalities of layer “A” and layer “B” are not substantially changed by the intermediate layer(s).

The following definitions and abbreviations are to be used for the interpretation of the claims and the specification. As used herein, the terms “comprises,” “comprising,” “includes,” “including,” “has,” “having,” “contains” or “containing,” or any other variation thereof, are intended to cover a non-exclusive inclusion. For example, a composition, a mixture, process, method, article, or apparatus that comprises a list of elements is not necessarily limited to only those elements but can include other elements not expressly listed or inherent to such composition, mixture, process, method, article, or apparatus.

For purposes of the description hereinafter, the terms “upper,” “lower,” “right,” “left,” “vertical,” “horizontal,” “top,” “bottom,” and derivatives thereof shall relate to the described structures and methods, as oriented in the drawing figures. The terms “overlying,” “atop,” “on top,” “positioned on” and “positioned atop” mean that a first element, such as a first structure, is present on a second element, such as a second structure, wherein intervening elements such as an interface structure can be present between the first element and the second element. The term “direct contact” means that a first element, such as a first structure, and a second element, such as a second structure, are connected without any intermediary conducting, insulating or semiconductor layers at the interface of the two elements. It should be noted, the term “selective to,” such as, for example, “a first element selective to a second element,” means that a first element can be etched, and the second element can act as an etch stop.

For the sake of brevity, conventional techniques related to semiconductor device and integrated circuit (IC) fabrication may or may not be described in detail herein. Moreover, the various tasks and process steps described herein can be incorporated into a more comprehensive procedure or process having additional steps or functionality not described in detail herein. In particular, various steps in the manufacture of semiconductor devices and semiconductor-based ICs are well known and so, in the interest of brevity, many conventional steps will only be mentioned briefly herein or will be omitted entirely without providing the well-known process details.

In general, the various processes used to form a micro-chip that will be packaged into an IC fall into four general categories, namely, film deposition, removal/etching, semiconductor doping and patterning/lithography.

Deposition is any process that grows, coats, or otherwise transfers a material onto the wafer. Available technologies include physical vapor deposition (PVD), chemical vapor deposition (CVD), electrochemical deposition (ECD), molecular beam epitaxy (“MBE”) and more recently, atomic layer deposition (ALD) among others. Another deposition technology is plasma enhanced chemical vapor deposition (PECVD), which is a process that uses the energy within the plasma to induce reactions at the wafer surface that would otherwise require higher temperatures associated with conventional CVD. Energetic ion bombardment during PECVD deposition can also improve the film's electrical and mechanical properties.

Removal/etching is any process that removes material from the wafer. Examples include etch processes (either wet or dry), chemical-mechanical planarization (CMP), and the like. One example of a removal process is ion beam etching (IBE) or milling. In general, IBE refers to a dry plasma etch method which utilizes a remote broad beam ion/plasma source to remove substrate material by physical inert gas and/or chemical reactive gas means. Like other dry plasma etch techniques, IBE has benefits such as etch rate, anisotropy, selectivity, uniformity, aspect ratio, and minimization of substrate damage. Another example of a dry removal process is reactive ion etching (RIE). In general, RIE uses chemically reactive plasma to remove material deposited on wafers. With RIE the plasma is generated under low pressure (i.e., a vacuum state) by an electromagnetic field. High-energy ions from the RIE plasma attack the wafer surface and react with it to remove material.

Semiconductor doping is the modification of electrical properties by doping, for example, transistor sources and drains, generally by diffusion and/or by ion implantation. These doping processes are followed by furnace annealing or by rapid thermal annealing (“RTA”). Annealing serves to activate the implanted dopants. Films of both conductors (e.g., poly-silicon, aluminum, copper, etc.) and insulators (e.g., various forms of silicon dioxide, silicon nitride, etc.) are used to connect and isolate transistors and their components. Selective doping of various regions of the semiconductor substrate allows the conductivity of the substrate to be changed with the application of voltage. By creating structures of these various components, millions of transistors can be built and wired together to form the complex circuitry of a modern microelectronic device.

Semiconductor lithography is the formation of three-dimensional relief images or patterns on the semiconductor substrate for subsequent transfer of the pattern to the substrate. In semiconductor lithography, the patterns are formed by a light sensitive polymer called a photo-resist. To build the complex structures that make up a transistor and the many wires that connect the millions of transistors of a circuit, lithography and etch pattern transfer steps are repeated multiple times. Each pattern being printed on the wafer is aligned to the previously formed patterns and slowly the conductors, insulators and selectively doped regions are built up to form the final device.

Turning now to an overview of technologies that are more specifically relevant to aspects of the present disclosure, magnetoresistive random-access memory (“MRAM”) devices using magnetic tunnel junctions (“MTJ”) are one option to replace existing eDRAM technologies. MRAM is a non-volatile memory, and this benefit is a driving factor that is accelerating the development of this memory technology.

Spin-transfer torque magnetic random-access memory (STT-MRAM) is an advanced nonvolatile memory that benefits from fast switching times (<10 ns) and even faster switching times (˜2 ns) which is required for last level cache or eDRAM replacement. Magnetic tunnel junction (MTJ) stacks for providing STT-MRAM devices with such fast switch times need to have a low moment free layer while still providing a sufficiently high retention time and tunnel magnetoresistance (TMR). Certain ordered alloys allow fast switching times as they provide the required magnetic properties. Relatively thin layers of magnetic material will have a low magnetic moment, which is desirable for obtaining fast switch times. The magnetic material forming the free layer should, in addition to having a low magnetic moment, provide significant retention. Mn₃Ge is a good choice for the free layer of a MTJ stack as it is a ferrimagnetic system, meaning its magnetization can be relatively low. For example, ordered Mn₃Ge free layers can be engineered to have a low magnetic moment and very high effective anisotropy field. Moreover, Mn₃Ge can also be engineered for good retention (e.g., 1-10 years of retention corresponding to an energy barrier between 0 and 1 state of about 50-60 k_{B}T for a memory device having a diameter of about 35 nm) while having a low magnetic moment. It will be appreciated that the intrinsic magnetization of Mn₃Ge is not a given and that it may change with composition details and strain. The anisotropy field may likewise change depending on intrinsic magnetization and strain, and may be greater than 4 T.

CoFeB free layers have been employed in MTJ stacks and have been shown to provide reliable switching. Bulk Mn₃Ge forming a thick, unstrained film has a magnetization of about one tenth of CoFeB(˜100 emu/cm3 vs ˜1000-1500 emu/cm3). Engineered Mn₃Ge films can have one fifth the magnetization of CoFeB down to zero net magnetization(˜200 emu/cm3 down to 0 emu/cm3). While MTJ devices having CoFeB free layers can provide fast write times, an advantage of Mn₃Ge over CoFeB and other high moment magnetic materials is the reduced penalty to pay in terms of higher switching voltages and currents when reducing write times. Write times of less than twenty nanoseconds (20 ns) are desirable advanced memory applications. High write speeds of 10 ns or less may be obtainable using MTJ pillars in accordance with one or more embodiments.

Magnetic alloys comprising Heusler materials can be used as free layers in MTJ stacks if grown on highly textured and ordered seed layer materials. The seed layer needs to “force” the ordered alloy (e.g., Mn₃Ge) into a desired structure, which in the case of Mn₃Ge is a tetragonal structure with the long axis being perpendicular to the film plane. The seed layer should also have a lattice constant that provides strain to the ordered alloy. In general, a lattice constant or lattice parameter is one of the physical dimensions and angles that determine the geometry of the unit cells in a crystal lattice, and is proportional to the distance between atoms in the crystal.

MTJ stack films can be deposited using, for example, physical vapor deposition (PVD), ion beam deposition (IBD) or other techniques. The patterning of the MTJ stack films to form pillars is accomplished by a stack etching process. Ion milling (ion beam etching or IBE) is a known MTJ stack etching technique.

Advanced STT-MRAM application require fast switching times (<10 ns), the most advanced application of STT-MRAM for last level cache or eDRAM replacement requiring ˜2 ns. MTJ stacks providing STT-MRAM devices with such fast switch times need to have a low moment while still providing a sufficiently high Magnetoresistance (TMR) and retention.

Ordered alloys are promising material for fast switching as they provide the required magnetic properties. In initial experiments we have shown ordered Mn₃Ge free layers having a low magnetic moment per area (Mₛt) of 0.02 memu/cm² and very high H_{K}. (for Mn₃Ge H_{K}=4 −10 T) For comparison currently used CoFeB free layers have Mₛt's in the order of ˜0.2 memu/cm² and H_{K} values of 0.2-1 T. Ordered Mn₃Ge has only ˜0-10% of the magnetization that “traditional” free layer materials have.

As explained above “traditional” free layer materials, as CoFeB free layers, do not support high switching speeds, because CoFeB has a too a high magnetic moment.

Growing Mn₃Ge material is challenging. Many magnetic alloys like Heusler materials require highly textured and ordered seed layer materials. The seed layer has to force the ordered alloy (i.e., the Mn₃Ge) into the desired tetragonal structure. It must also have a lattice constant which provides strain to the ordered alloy.

Tensile strain of a Mn₃Ge free layer is desired as the spin polarization of the strained compound is greater than that of bulk Mn₃Ge. In general, in particle physics, spin polarization refers to the degree to which the spin, i.e., the intrinsic angular momentum of elementary particles, is aligned with a given direction. This property may pertain to the spin, hence to the magnetic moment, of conduction electrons in ferromagnetic metals, such as iron, giving rise to spin-polarized currents. Bulk Mn₃Ge has a lattice constant of 3.82 Å and the spin polarization is about 58%. If the Mn₃Ge lattice is “stretched” above 4 Å, the spin polarization increases to about 90%. High spin polarization is necessary for reducing the switching current and for a low read current at fast read times. A Mn₃Ge free layer accordingly should be grown on a crystalline template having a lattice constant larger than 4 Å to facilitate ordered growth of such a free layer.

A stoichiometric CoAl alloy (50:50 atomic ratio, non-magnetic alloy) is a template which allows the growth of Mn₃Ge. CoAl has a lattice constant of 2.85 Å. Therefore the diagonal (110 directions) of the cubic cell is 4.03 Å, which allow the formation of a tensile strained Mn₃Ge.

When magnesium oxide is deposited onto an amorphous CoFeB layer, it naturally forms a highly textured (001) oriented structure by itself even for ultra-thin layers of 8-10 Å thickness. Other amorphous layers like ZrCo will also allow for highly textured MgO growth. The MgO has a cubic “NaCl” structure with a lattice constant of 4.25 Å.

CoAl also has a cubic structure, but with a “CsCl” structure. CoAl has a lattice constant of 2.85 Å. If CoAl is grown without the right template, it grows as a mixture of (001) and (011) oriented crystallites with respect to the film axis. For Mn₃Ge templating only (001) crystallites are desired. If the unit cell of the CoAl is rotated 45 degrees, the lattice spacing in (011) direction is 4.03 Å, which is similar to the lattice constant of (001) MgO of 4.25 Å. Growing (001) oriented CoAl on 8-10 Å thick MgO may be achieved, and a thinner seed layer may be used as compared with related MTJ devices.

This CoAl template enables the growth of strained Mn₃Ge. Mn₃Ge has a natural lattice constant of 3.82 Å, so growing it on the 4.03 Å CoAl template will lead to the formation of a tensile strained Mn₃Ge as free layer material.

Exchange coupled free layer means that the free layer consists of at least two magnetic sublayers which are coupled through a coupling layer. This coupling layer may be non-magnetic. Coupled means that at equilibrium the magnetizations of both (or more) sublayers of the free layer are all parallel to each other. In certain devices, coupled free layers are called exchange coupled composite (ECC) layers. ECC layers are used in certain MTJ devices. ECC layers allow reducing the write current and voltage compared to a non-ECC free layer with same retention time. The first free layer switches easily having a low switching current (I_{c}), and because the two magnetic free layers are coupled together magnetically through the thin ECC spacer, the second free layer follows the switching of the first free later. The ECC spacer has to be thin, that in equilibrium the first and second magnetic free layers are always parallel. In CoFeB based free layer stacks ECC spacer materials include a single metal layer, such as W, Mo, Ta or Nb, or an oxide like MgO or Al₂O₃. However, there is no coherent epitaxial relation throughout such stacks. Therefore, certain of these ECC spacer materials will not work in the context of ordered alloys, as they would break the crystallinity and not allow for ordering of the second (and more) additional part of the free layer. In order to preserve crystalline coherence throughout the stack, the ECC spacer material for ordered alloy free layers needs to be an ordered alloy itself. However, AlCo and other CsCl structured alloys like IrAl, GaCo, can be used as ECC spacer materials and allow coherent crystallinity between all parts of the ECC free layer.

Contrary to traditionally used CoFeB layers, the anisotropy field (Hₖ) of ordered alloys is a bulk property, not an interface property. For free layers including CoFeB, the Hₖ is defined by the interface of CoFeB and MgO, and also by the diameter of the MTJ pillar. To reach a high retention (E_{b}), a relatively large pillar diameter may be needed (100-120 nm). Large MTJ diameters require higher switching currents, result in low efficiency, and require more switching energy. The activation energy (retention) E_{b} is proportional to the product of the anisotropy field (Hₖ) and the free layer magnetic moment (m) according to the following.

E_{b}=½m Hₖ

In ordered alloys the PMA (i.e., anisotropy field) can be easily increased by increasing the thickness of the ordered alloy. The thicker the layer, the better the crystallinity and with it, the PMA. High PMA may be needed for good retention (high E_{b}). Therefore, the second free layer in the ECC structure of the present embodiments is thicker. The first free layer is thinner to keep the switching current to energy ratio low.

The magnetic moment of a free layer alloys may be represented by the following.

Magnetic Moment=magnetization of the layer material*layer thickness

Iron/CoFeB has a Magnetization of 1000-1700 emu/cm³ depending on their composition, annealing conditions and adjacent layers. Mn₃Ge has a magnetization of 100-200 emu/cm³. Mn₃Ge has a factor of 5-15 times lower moment than the same thickness of CoFeB. CoFeB layers have moments of 0.15-0.20 memu/cm². Thin Mn₃Ge can have a moment below 0.1 emu/cm² (e.g., 0.01 memu/cm²). In the present embodiments, the first free layer has a low moment, requiring a lower write current. Since the first and second free layers are coupled via the lattice matched ordered alloy ECC spacer, the second free layer will follow the easily writable first free layer.

The flowcharts and cross-sectional diagrams in the Figures illustrate methods of manufacturing MTJs according to various embodiments. In some alternative implementations, the manufacturing steps in the flowcharts may occur in a different order than that which is noted in the Figures. Moreover, any of the layers depicted in the Figures may contain multiple sublayers.

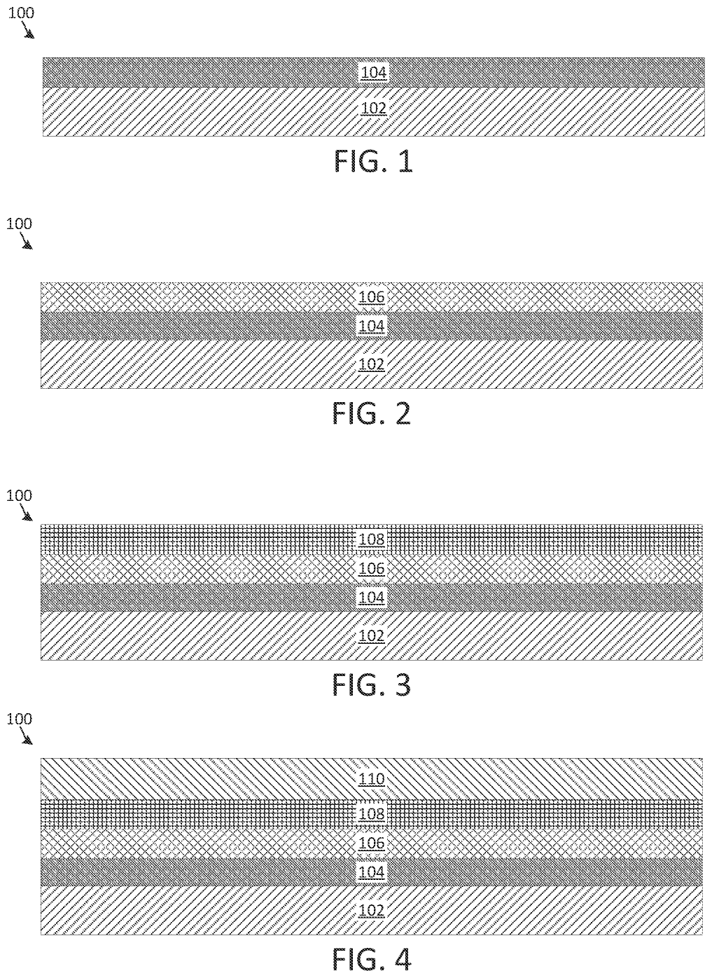

Referring now to the drawings in which like numerals represent the same or similar elements and initially to FIG. 1, an exemplary method of manufacturing an MRAM device including a MTJ device 100 to which the present embodiments may be applied is shown. As shown in FIG. 1, a substrate 102 is provided. The substrate 102 may be a bulk-semiconductor substrate. In one example, the bulk-semiconductor substrate may be a silicon-containing material. Illustrative examples of silicon-containing materials suitable for the bulk-semiconductor substrate include, but are not limited to, silicon, silicon germanium, silicon germanium carbide, silicon carbide, polysilicon, epitaxial silicon, amorphous silicon, and multi-layers thereof. Although silicon is the predominantly used semiconductor material in wafer fabrication, alternative semiconductor materials can be employed, such as, but not limited to, germanium, gallium arsenide, gallium nitride, cadmium telluride, and zinc selenide. Although not depicted in the present figures, the semiconductor substrate 102 may also be a semiconductor on insulator (SOI) substrate. Other illustrative examples of semiconductor materials that can be used in the present application include, but are not limited to, silicon (Si), a silicon germanium (SiGe) alloy, a silicon germanium carbide (SiGeC) alloy, germanium (Ge), a III/V compound semiconductor, an II/VI compound semiconductor or a multilayered stack including at least two semiconductor materials (e.g., a multilayered stack of Si and SiGe). In one embodiment (depicted in the drawings of the present application), the semiconductor substrate 102 is entirely composed of at least one semiconductor material. It should be appreciated that the substrate 102 may be comprised of any other suitable material(s) than those listed above. In certain embodiments, the substrate layer may comprise a back end of line (BEOL) interconnect layer.

As shown in FIG. 1, a starting structure for the MTJ device 100 includes a bottom amorphous layer 104 formed on the substrate 102 layer. The bottom amorphous layer 104 may comprise, for example, a tantalum or tantalum nitride (TaN) layer deposited on the substrate 102 by a physical vapor deposition (PVD), sputtering or other suitable process. The bottom amorphous layer 104 may have a thickness of about 20 Å.

Referring now to FIG. 2, this figure is a cross-sectional view of the MTJ device 100 of FIG. 1 at a subsequent stage of the manufacturing process. As shown in FIG. 2, a thin, amorphous template layer 106 is formed on the bottom amorphous layer 104. The amorphous template layer 106 comprises, for example, CoFeB and may be deposited by sputtering. The amorphous template layer 106 may have a thickness of about 5 Å. However, it should be appreciated that other thicknesses of the amorphous template layer 106 may be used. A ZrCo based amorphous template layer 106 may be used in an alternative embodiment. It will be noted that the amorphous template layer 106 only needs to be amorphous upon deposition and during subsequent deposition of an MgO seed layer as described below. The amorphous template layer 106 may crystallize later in the process such that the final structure may include a crystalline layer beneath the MgO seed layer.

Referring now to FIG. 3, this figure is a cross-sectional view of the MTJ device 100 of FIG. 2 at a subsequent stage of the manufacturing process. As shown in FIG. 3, a first seed layer 108 is formed on the amorphous template layer 104. The first seed layer 108 may comprise, for example, magnesium oxide (MgO). A highly textured (001) oriented structure is naturally formed when MgO is deposited on an amorphous template layer 106 such as amorphous CoFeB. A thin MgO first seed layer 108 is deposited on the amorphous template layer 106, naturally forming a highly textured, cubic (NaCl-like) structure with a lattice constant of 4.25 Å. In general, NaCl has a cubic unit cell. It is best thought of as a face-centered cubic array of anions with an interpenetrating face-centered cubic (FCC) cation lattice (or vice-versa). FCC refers to a cubic lattice with the face positions fully equivalent to each of the eight corners. FCC structures are, as the name implies, based around “faces” of a cube with an atom at each of the corners and one at the center of each face. As discussed below, the thin first seed layer 108, having a thickness of about 6-10 Å in exemplary embodiments, enables mainly (001) textured CoAl crystallites to be formed thereon. In general, (001) refers to a crystal lattice plane that is described by a mathematical description known as a Miller Index. In an exemplary embodiment, the first seed layer 108 is deposited at ambient temperature by sputtering and has a thickness of three nanometers (3 nm) or less.

Referring now to FIG. 4, this figure is a cross-sectional view of the MTJ device 100 of FIG. 3 at a subsequent stage of the manufacturing process. As shown in FIG. 4, a chemical templating layer (CTL) or second seed layer 110 is deposited on the first seed layer 108. In an exemplary embodiment, the second seed layer 110 is a non-magnetic, crystalline CoAl layer deposited on the first seed layer 108 by sputtering. The second seed layer 110, in one exemplary embodiment, is a stoichiometric CoAl alloy having a 50:50 atomic ratio. Stoichiometric CoAl alloy is a template that allows the growth of a Mn₃Ge free layer. In certain embodiments, the second seed layer 110 includes a non-magnetic alloy, and has a thickness of, for example, 30-50 Å. CoAl has also a cubic structure, with a lattice constant of 2.85 Å. If the unit cell of the CoAl is rotated 45 degrees, the lattice spacing in (011) direction is 4.03 Å, which is similar to the lattice constant of (001) MgO. Therefore, when grown on MgO, CoAl having a 50:50 atomic ratio forms mainly (001) crystallites having a CsCl structure and lattice spacing in the (011) direction of 4.03 Å. The second seed layer 110, in addition to enabling mainly (001) textured CoAl crystallites, is an electrical insulator that is non-magnetic and prevents spin pumping. In certain embodiments, the second seed layer 110 includes at least one of AlCo and AlNi.

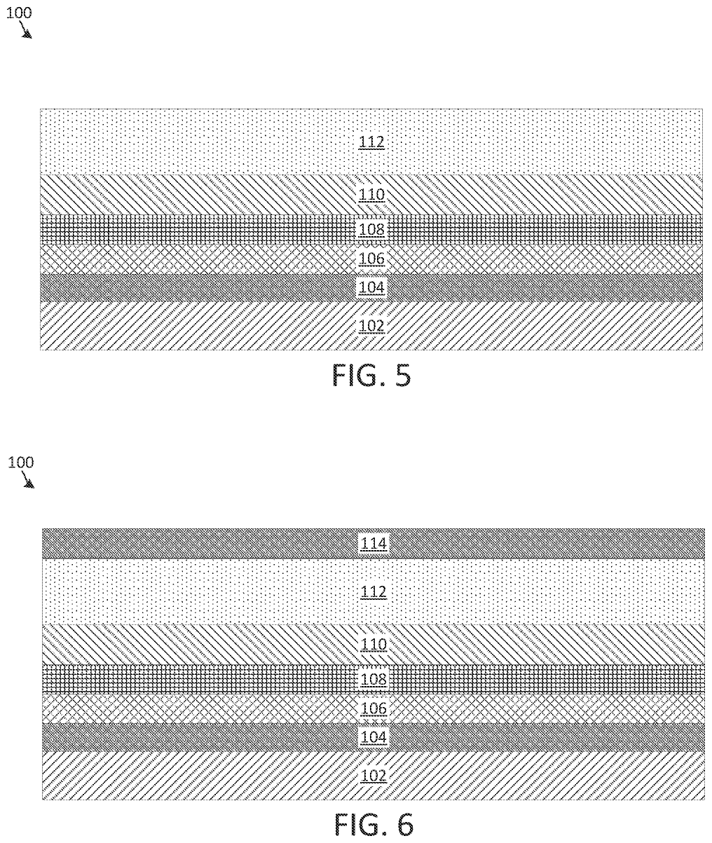

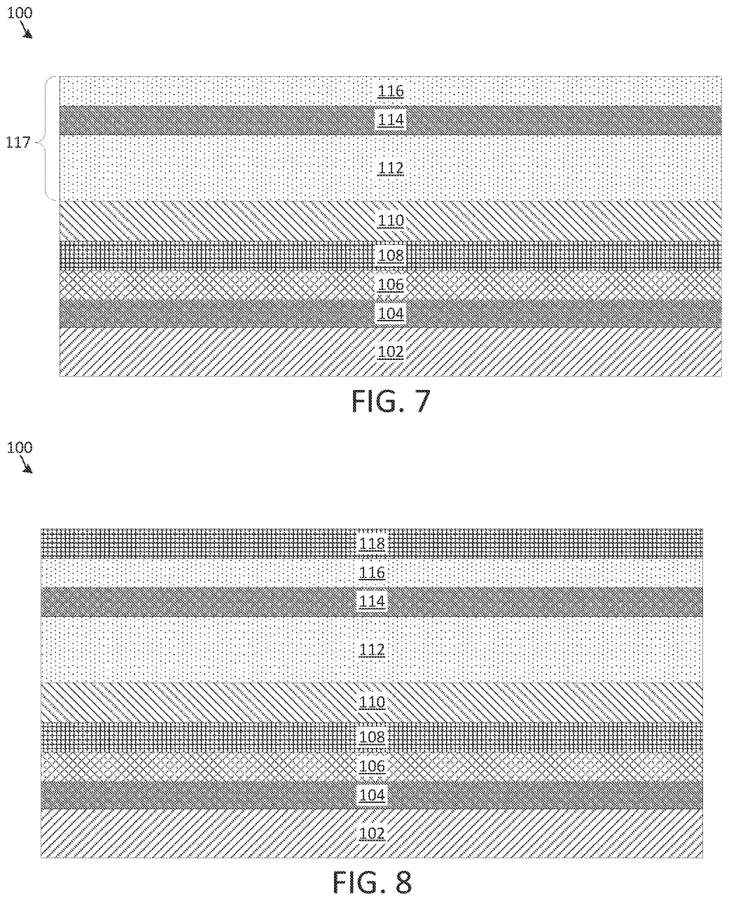

Referring now to FIG. 5, this figure is a cross-sectional view of the MTJ device 100 of FIG. 4 at a subsequent stage of the manufacturing process. As shown in FIG. 5, a first free layer 112 of the overall free layer structure 117 (see, FIG. 7) is formed that includes a tensile strained Mn₃Ge free layer. In general, tensile strain is an effect of strain engineering, which refers to a general strategy employed in semiconductor manufacturing to enhance device performance. Performance benefits are achieved by modulating strain, as one example, in the transistor channel, which enhances electron mobility (or hole mobility) and thereby conductivity through the channel.

The first free layer 112 can be formed epitaxially on the second seed layer 110 (or CoAl chemical templating layer (CTL)) having the cubic CsCl structure obtained by growing the CoAl on the MgO first seed layer 108. CsCl has a cubic structure that consists of an infinite chain of ions. The Cs ions sit at the eight corners of the cube and the Cl ions sit at the center of the cube. Thus, the CsCl structure is not a body-centered lattice since that requires the same ion to occupy the edges and center. Also, in crystallography, the cubic (or isometric) crystal system is a crystal system where the unit cell is in the shape of a cube. Terms “epitaxially growing and/or depositing” and “grown epitaxially” mean the growth of a material on a deposition surface in which the material being grown has the same crystalline characteristics as the deposition surface. In an epitaxial deposition process, the chemical reactants are controlled, and the system parameters are set so that the depositing atoms arrive at the deposition surface of the semiconductor substrate with sufficient energy to move around on the surface and orient themselves to the crystal arrangement of the atoms of the deposition surface. The simplified seed layer structure comprising the MgO first seed layer 108 and the second seed layer 110, which preferably has a thickness of less than 100 Å, facilitates the growth of an ordered alloy material such as Mn₃Ge as the first free layer 112. The CoAl second seed layer 110 now has a lattice of 4.03 Å, which allows the formation of the tensile strained Mn₃Ge first free layer 112. Bulk Mn₃Ge has a lattice constant of 3.82 Å, so growing it on the 4.03 Å CoAl template of the second seed layer 110 will lead to the formation of a tensile strained Mn₃Ge as the first free layer material. The first free layer 112 is thicker than the later deposited second free layer 116 (see, FIG. 7). The thicker thickness of the first free layer 112 will lead to a high PMA (Hₖ) and a high retention (E_{b}). In certain examples, the magnetic moment of the first free layer may be about <0.05 memu/cm², and its PMA (Hₖ) may be in the range of about 1-10 Tesla. The thickness of the first free layer 112 in one exemplary embodiment ranges from about 30-100 Å, while the MgO based second seed layer 110 has a thickness of 10 Å or less. The second seed layer 110 should have sufficient thickness to ensure proper texturing (tetragonal) of the subsequently grown first free layer 112 and the introduction of strain therein to avoid perpendicular magnetic anisotropy (PMA) loss or other degradation of magnetic properties.

In embodiments where the first free layer 112 comprises an ordered alloy having a lattice constant different from that of Mn₃Ge, a second seed layer 110 having a difference lattice constant than that of CoAl may be employed. Ordered Heusler alloys besides Mn₃Ge may be employed as first free layers 110 (or as sublayers of multi-layer free layers) in some embodiments and may require different CTLs grown on MgO for providing the desired strain on the first free layer 110. Such ordered magnetic alloys include, for example, Mn₃Ga, Co₂MnSn, Mn₃Sn, and Mn₃Sb. The term “ordered magnetic alloy” is understood as a magnetic alloy that has a lattice structure in a pattern in which atoms of one element occupy particular sites in the pattern and atoms of at least one other element occupy other sites in the pattern.

Materials other than CoAl may be employed as the second seed layer 110 provided they have the CsCl structure, (001) oriented texture, and appropriate lattice parameters. In embodiments wherein strain is to be provided on a Heusler alloy comprising the first free layer, the lattice parameter of the second seed layer 110 should be in a range that is sufficiently meaningful to strain the Heusler alloy towards the targeted lattice structure. In some embodiments, the second seed layer 110 (or chemical templating layer) may comprise NiAl, IrAl, or CoGa. Multi-layer chemical templating layers comprising two or more distinct layers may be employed in further alternative embodiments. A multi-layer structure such as CoAl| CoIr/CoAl may form a second seed layer 110 layer in one or more embodiments. It will be appreciated that if a Heusler alloy (i.e., for the first free layer 112) having ideal or satisfactory properties (e.g., high TMR and perpendicular magnetic anisotropy (PMA), low magnetic moment (Mst)) in an unstrained state were available, such an alloy may not require growth on a chemical templating layer (i.e., the second seed layer 110) that provides strain thereto.

As discussed above, tensile strain of a textured Mn₃Ge free layer (e.g., the first free layer 112) is desired as the spin polarization of the strained compound is greater than that of bulk Mn₃Ge. High spin polarization is necessary for reducing the switching current and for a low read current. The CoAl template (i.e., the second seed layer 110) as provided in accordance with the teachings herein, having a lattice constant greater than 4 Å, enables growth of a strained Mn₃Ge free layer having a spin polarization of about ninety percent (90%). Free layers such as Mn₃Ge free layers can be grown using various known processes, including sputtering. Bottom free layer MTJs, wherein the tunnel barrier and reference layer are formed above the free layer, are provided in one or more exemplary embodiments.

Referring now to FIG. 6, this figure is a cross-sectional view of the MTJ device 100 of FIG. 5 at a subsequent stage of the manufacturing process. As shown in FIG. 6, a spacer layer 114 is formed on top of the first seed layer 112 and is part of the overall multilayer structure of the free layer structure 117 (see, FIG. 7). In certain embodiments, the material of the spacer layer 114 may be a CoAl ECC. In certain embodiments, the spacer layer includes at least one of GaCo, AlRh, AlIr, of GaRh and GaIr. In examples where the spacer layer 114 comprises CoAl, the CoAl ECC is a stoichiometric CoAl alloy (50:50 atomic ratio or less Cobalt, non-magnetic alloy) having the same lattice constant and composition as the CoAl seed layer (i.e., the second seed layer 108). As the spacer layer 114 will be sandwiched between the first free layer 112 and the second free layer 116 (see, FIG. 7), it will be fully strained and adjust itself to the lattice of the surrounding CoAl. The non-magnetic spacer layer 114 including the CoAl has to be thin enough that the two magnetic free layers (i.e., first free layer 112 and second free layer 116) are coupled together magnetically, so that in equilibrium the first free layer 112 and second free layer 116 are always parallel. Other Heusler alloys may use alternate seed and non-magnetic spacer materials, such as manganese nitride (MnN) or vanadium nitride (VN). In certain embodiments, the spacer layer may have a thickness of about 3-10 Å. In certain embodiments, the spacer layer 114 has a greater lattice parameter (or lattice constant) than the first seed layer 108 and/or the second seed layer 110.

Referring now to FIG. 7, this figure is a cross-sectional view of the MTJ device 100 of FIG. 6 at a subsequent stage of the manufacturing process. As shown in FIG. 7, a second free layer 116 is formed on the spacer layer 114. Thus, the overall free layer structure 117 includes the first free layer 112, the spacer layer 114 and the second free layer 116. In certain embodiments, the second free layer 116 may comprise the same material as that of the first free layer 112 (e.g., Mn₃Ge). The spacer layer 114 (e.g., comprising a CoAl ECC layer) forms another template (i.e., similar to the template of the second seed layer 110) with a lattice constant of 4.03 Å, which allows the formation of a tensile strained Mn₃Ge layer. Bulk Mn₃Ge has a lattice constant of 3.82 Å, so growing it on the 4.03 Å CoAl template of the spacer layer 114 will lead to the formation of a tensile strained Mn₃Ge as the second free layer 116 material. In certain embodiments, the second free layer 116 has to be thin to enable fast switching of the whole free layer structure 117. A thinner second free layer 116 results in a lower moment. The magnetic moment of the second free layer is <0.025 memu/cm², and PMA (Hₖ) is in the range of 0.1-2.5 Tesla. In certain embodiments, a thickness of the second free layer 116 is thinner than the first free layer 112, and may be in a range of about 10-20 Å.

Referring now to FIG. 8, this figure is a cross-sectional view of the MTJ device 100 of FIG. 7 at a subsequent stage of the manufacturing process. As shown in FIG. 8, a tunnel barrier layer 118 is grown on the second free layer 116. The tunnel barrier layer 118 comprises a thin dielectric layer of barrier material. In an exemplary embodiment, the barrier material is a crystalline MgO layer having an (001) texture and a thickness of less than two nanometers (2 nm). MgO grown on Mn₃Ge will, like the MgO seed layer, be (001) textured. Grain formation differs from the manner in which MgO grains are obtained when grown on CoFeB in forming the MgO seed layer. If MgO is grown on an amorphous template layer such as a CoFeB layer, it forms grains which have a (001) texture, but which are randomly oriented with respect to the in-plane orientations. During anneal, the CoFeB crystallizes, and the grains follow the MgO orientations. If MgO is grown on crystalline Mn₃Ge as in an exemplary embodiment, the Mn₃Ge grains (at least in an ideal case) determine the MgO grain size and in-plane orientation. The MgO aligns to the existing lattice of the Mn₃Ge. The thin seed layer (i.e., the spacer layer 114) of the free layer structure 117 includes a well crystallized and textured CoAl CTL as grown on an MgO seed layer. The second free layer 116, grown, in this embodiment, epitaxially on the CoAl CTL spacer layer 114, is, again in this embodiment, textured and strained by both the CoAl of the spacer layer 114 and the textured MgO tunnel barrier layer 116, and has substantially uniform crystallinity throughout. Mn₃Ge thin films have low magnetic moments per area (0.02 memu/cm²) and high perpendicular anisotropy fields Hₖ.

The tunnel barrier layer 118 is sufficiently thin that quantum-mechanical tunneling of the charge carriers occurs between the adjoining magnetic layers. The barrier material may alternatively comprise other dielectric materials including, but not limited to, aluminum oxide (AlOₓ) and titanium oxide (TiOₓ), either of which can be deposited using standard sputtering techniques. In embodiments wherein the tunnel barrier layer 118 material is crystalline MgO and the spacer layer 114 is CoAl, the Mn₃Ge material of the second free layer 116 has a desired tetragonal crystal structure, is strained by both the tunnel barrier layer 118 and the spacer layer 114, has a relatively low magnetic moment, and has high magnetic isotropy (Hₖ). The thin seed layer structure facilitates the growth of the tunnel barrier layer 116 without degrading the TMR ratio. Imperfections that can propagate from relatively thick seed layers into subsequently deposited layers and cause the formation of a rough tunnel barrier base portion are reduced or avoided. As the tunnel barrier can be very thin, a base portion exhibiting surface roughness can adversely impact its performance.

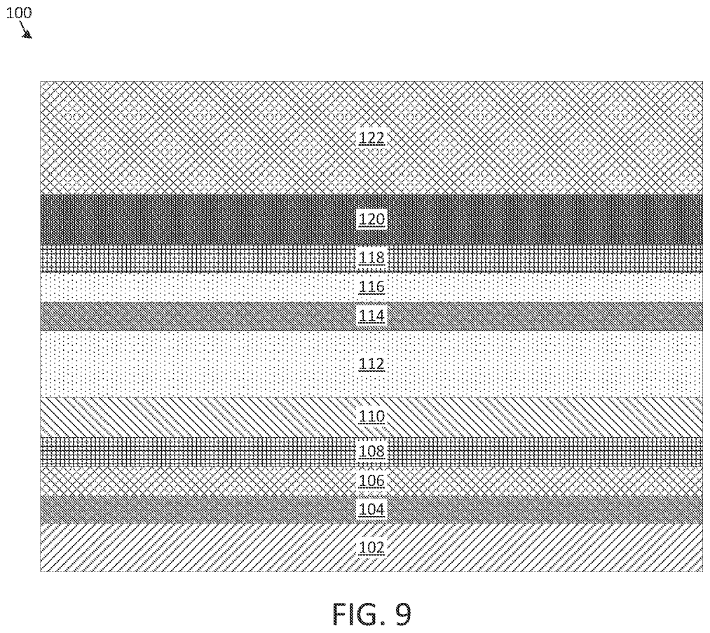

Referring now to FIG. 9, this figure is a cross-sectional view of the MTJ device 100 of FIG. 8 at a subsequent stage of the manufacturing process. As shown in FIG. 9, a reference layer structure adjoins the tunnel barrier layer 118 and may comprise multiple layers, including a pinning layer, ferromagnetic layers and a spacer layer between the ferromagnetic layers. When a bias is applied to the MTJ device 100, electrons that are spin polarized by the magnetic layers traverse the insulating barrier through a process known as quantum tunneling to generate an electric current, the magnitude of which depends on an orientation of magnetization of the magnetic layers. The MTJ device 100 will exhibit a low resistance when a magnetic moment of the free layer structure 117 is parallel to the fixed (reference) layer magnetic moment, and it will exhibit a high resistance when the magnetic moment of the free layer structure 117 is oriented anti-parallel to the fixed layer magnetic moment. The reference layer structure in an exemplary embodiment includes a CoFeB layer 120 for creating spin polarization. It further includes a pinned synthetic antiferromagnetic (“SAF”) layer 122 above the CoFeB layer 120. The CoFeB layer adjoins a reference layer including a multilayer-based synthetic antiferromagnet (SAF) structure. SAF structures include two magnetic layers antiferromagnetically coupled through a metallic spacer.

Referring again to FIG. 9, an MTJ pillar can be formed from the MTJ stack structure of the MTJ device 100 following deposition and patterning of a hard mask (not shown) and ion beam etching of the MTJ device 100 stack structure that is deposited over the substrate 102, for example a silicon or silicon oxide substrate layer. The etching of the MTJ device 100 stack structure results in the formation of vertical pillars (not shown) from the MTJ device 100 stack structure, and each of the pillars include a magnetic tunnel junction comprised of a reference layer (i.e., CoFeB layer 120 and SAF layer 122) formed over the tunnel barrier layer 118, and the tunnel barrier layer 118 formed over the free layer structure 117. In certain examples, the tunnel barrier layer 118 comprises MgO. The free layer structure 117 may be formed of magnetically active metals such as an ordered magnetic alloy, and may comprise multiple layers. In the example shown in FIG. 8, the free layer structure 117 includes the first free layer 112, the spacer layer 114 and the second free layer 116.

In certain embodiments, the MTJ pillars are encapsulated within a dielectric layer (not shown) formed from silicon oxide or a low-x dielectric material such as SiCOH. Chemical vapor deposition (CVD), including plasma-enhanced CVD, may be used for the deposition of low-x (x less than 4.0) dielectric materials such as porous SiCOH. The bottom electrodes of the MTJ pillars are electrically connected in some embodiments to a metal contact via (not shown) which is, in turn, electrically connected to another metal layer (not shown). It will be appreciated that the techniques disclosed herein are applicable to the fabrication of MTJ-containing pillars having various configurations, including but not limited to double MTJ structures, and made from materials other than those described with respect to the exemplary pillar described above. Pillars as described herein have various applications, including within STT-MRAM structures and SOT-MRAM (spin-orbit torque MRAM) structures.

As discussed above, in ordered alloys, the PMA (i.e., anisotropy field) can be easily increased by increasing the thickness of the ordered alloy. The thicker the layer, the better the crystallinity and with it its PMA. High PMA is needed for good retention (high E_{b}). Therefore, the first free layer 112 in the present embodiments is thicker. Also, the second free layer 116 is thinner to keep the switching current to energy ratio low.

Embodiments of the present disclosure relate to a magnetic tunnel junction device includes a first seed layer, a second seed layer on the first seed layer, and a free layer structure on the second seed layer. The free layer structure includes a first free layer, a spacer layer formed on the first free layer, and a second free layer formed on the spacer layer. The first and second free layers each include an ordered magnetic alloy. A tunnel barrier layer is formed on the free layer structure, and a reference layer structure is formed on the tunnel barrier layer.

In certain embodiments, the first seed layer of the magnetic tunnel junction device comprises (001) textured magnesium oxide (MgO). The MgO has a cubic structure with a lattice constant of 4.25 Å. This may allow for subsequent formation of a first seed layer that includes, for example, a CoAl alloy.

In certain embodiments, the second seed layer of the magnetic tunnel junction device is a crystalline, non-magnetic chemical templating layer comprising CoAl. The CoAl alloy (e.g., a 50:50 atomic ratio, non-magnetic alloy, 30-50 Å) also has a cubic structure, with a lattice constant of 2.85 Å, and when the unit cell of the CoAl is rotated 45 degrees, the lattice spacing in (011) direction is 4.03 Å, which is similar to the lattice constant of (001) MgO. This may allow for subsequent formation of, for example, a tensile strained Mn₃Ge first free layer.

In certain embodiments, the ordered magnetic alloy of the magnetic tunnel junction device is a Heusler alloy. The Heusler alloy has lower moment than the same thickness of CoFeB. CoFeB layers have moments of 0.15-0.20 emu/cm². Thin Heusler alloys can have a moment below 0.1 emu/cm², i.e., 0.01 emu/cm². Therefore, the Huesler alloy of the first free layer has a low moment, requiring a lower switching current.

In certain embodiments, the first free layer and the second free layer of the magnetic tunnel junction device comprise at least one of Mn₃Ge, Mn₃Ga, Co₂MnSn, Mn₃Sn and Mn₃Sb. These alloys have a lower moment than the same thickness of CoFeB. CoFeB layers have moments of 0.15-0.20 emu/cm². Thin layers of these alloys can have a moment below 0.1 emu/cm², i.e., 0.01 emu/cm². Therefore, the alloys of the first free layer and the second free layer have a low moment, requiring a lower switching current.

In certain embodiments, the first free layer and the second free layer of the magnetic tunnel junction device each comprise a tensile strained Mn₃Ge layer. Thin layers of this alloy can have a moment below 0.1 emu/cm², i.e., 0.01 emu/cm². Therefore, the Mn₃Ge material of the first free layer and the second free layer have a low moment, requiring a lower switching current.

In certain embodiments, the first seed layer, the second seed layer, the free layer structure, and the tunnel barrier layer of the magnetic tunnel junction device comprise a layered stack having substantially uniform crystallinity. Uniform crystallinity of these layers may allow for an increase in the anisotropy field (PMA) of the MTJ device, and this may enable improved retention (high E_{b}).

In certain embodiments, the first free layer of the magnetic tunnel junction device has a thickness ranging from 30-100 Å, and the second free layer has a thickness ranging from 10-20 Å. Second free layer in this context refers to the part of the free layer being in direct contact with the tunnel barrier. Therefore, the first free layer in the magnetic tunnel junction device is thicker than the second free layer. The second free is thinner to keep the ratio of switching current to switching energy low. Since the first and second free layers are coupled via the lattice matched spacer layer, the first free layer will follow the easily switchable second free layer.

In certain embodiments, the second seed layer of the magnetic tunnel junction device has a greater lattice constant than the lattice constant of the first free layer. This may allow for subsequent formation of, for example, a tensile strained first free layer.

In certain embodiments, the spacer layer of the magnetic tunnel junction device is a crystalline, non-magnetic chemical templating layer comprising CoAl. This may allow for subsequent formation of, for example, a tensile strained second free layer including Mn₃Ge.

In certain embodiments, The magnetic tunnel junction device of claim 1, wherein the second seed layer and the spacer layer have the same lattice constant. Because the second free layer will be sandwiched in between the second seed layer and the spacer layer, it will be fully strained and adjust itself to the lattice of the surrounding materials.

In certain embodiments, the second free layer of the magnetic tunnel junction device is strained by the spacer layer, the first free layer and the second seed layer. This may also allow for the use of a lower switching current that is needed to reorient the magnetization of the magnetic free layer structure, thus improving the switching speed and further reducing write errors.

In certain embodiments, an MRAM storage device is provided. The MRAM storage device includes a magnetic tunnel junction device including a first seed layer, a second seed layer on the first seed layer, and a free layer structure on the second seed layer. The free layer structure includes a first free layer, a spacer layer formed on the first free layer, and a second free layer formed on the spacer layer, wherein the first and second free layers each include an ordered magnetic alloy. A tunnel barrier layer is provided on the free layer structure, and a reference layer structure is provided on the tunnel barrier layer. In the present embodiments, the first free layer and the second free layer are coupled via the lattice matched ordered alloy spacer layer, and the first free layer will follow the easily switchable second free layer. This may allow for keeping the ratio of switching current to switching energy to be lower. This may also allow for the use of a lower switching current that is needed to reorient the magnetization of the magnetic free layer structure, thus improving the switching speed and further reducing write errors.

In certain embodiments, the second seed layer of the MRAM storage device is a crystalline, non-magnetic chemical templating layer comprising CoAl. The CoAl alloy (e.g., a 50:50 atomic ratio, non-magnetic alloy, 30-50 Å) also has a cubic structure, with a lattice constant of 2.85 Å, and when the unit cell of the CoAl is rotated 45 degrees, the lattice spacing in (011) direction is 4.03 Å, which is similar to the lattice constant of (001) MgO. This may allow for subsequent formation of, for example, a tensile strained Mn₃Ge first free layer.

In certain embodiments, the ordered magnetic alloy of the MRAM storage device is a Heusler alloy. The Heusler alloy has lower moment than the same thickness of CoFeB. CoFeB layers have moments of 0.15-0.20 emu/cm². Thin Heusler alloys can have a moment below 0.1 emu/cm², i.e., 0.01 emu/cm². Therefore, the Huesler alloy of the first free layer has a low moment, requiring a lower switching current.

In certain embodiments, the first free layer and the second free layer of the MRAM storage device comprise at least one of Mn₃Ge, Mn₃Ga, Co₂MnSn, Mn₃Sn and Mn₃Sb. These alloys have a lower moment than the same thickness of CoFeB. CoFeB layers have moments of 0.15-0.20 emu/cm². Thin layers of these alloys can have a moment below 0.1 emu/cm², i.e., 0.01 emu/cm². Therefore, the alloys of the first free layer and the second free layer have a low moment, requiring a lower switching current.

In certain embodiments, the first free layer and the second free layer of the MRAM storage device each comprise a tensile strained Mn₃Ge layer. Thin layers of this alloy can have a moment below 0.1 emu/cm², i.e., 0.01 emu/cm². Therefore, the Mn₃Ge material of the first free layer and the second free layer have a low moment, requiring a lower switching current.

In certain embodiments, the first free layer of the MRAM storage device has a thickness ranging from 30-100 Å, and the second free layer has a thickness ranging from 10-20 Å. Therefore, the first free layer in the magnetic tunnel junction device is thicker than the second free layer. The second free is thinner to keep the ratio of switching current to switching energy low. Since the first and second free layers are coupled via the lattice matched spacer layer, the first free layer will follow the easily switchable second free layer.

In certain embodiments, the second seed layer of the MRAM storage device has a greater lattice constant than the lattice constant of the first free layer. This may allow for subsequent formation of, for example, a tensile strained first free layer.

It is to be appreciated that the various layers and/or regions shown in the accompanying figures may not be drawn to scale. Furthermore, one or more semiconductor layers of a type commonly used in such integrated circuit devices or other layers may not be explicitly shown in a given figure for ease of explanation. This does not imply that the semiconductor layer(s) or other layer(s) not explicitly shown are omitted in the actual integrated circuit device.

At least a portion of the techniques described above may be implemented in an integrated circuit. In forming integrated circuits, identical dies are typically fabricated in a repeated pattern on a surface of a semiconductor wafer. Each die includes a device described herein, and may include other structures and/or circuits. The individual dies are cut or diced from the wafer, then packaged as an integrated circuit. One skilled in the art would know how to dice wafers and package die to produce integrated circuits.

For clarity, the exemplary structures discussed above can be distributed in raw form (i.e., a single wafer having multiple unpackaged chips), as bare dies, in packaged form, or incorporated as parts of intermediate products or end products that benefit from having structures such as memory devices including magnetic tunnel junctions formed in accordance with one or more of the exemplary embodiments.

The descriptions of the various embodiments have been presented for purposes of illustration and are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A magnetic tunnel junction device comprising:
a seed layer; and
a free layer structure on the seed layer, the free layer structure comprising a first free layer, a spacer layer formed on the first free layer, and a second free layer formed on the spacer layer, wherein the first and second free layers each include an ordered magnetic alloy.

2. The magnetic tunnel junction device of claim 1, further comprising:
a tunnel barrier layer on the free layer structure; and
a reference layer structure on the tunnel barrier layer.

3. The magnetic tunnel junction device of claim 1, further comprising a base seed layer, the seed layer being formed on the base seed layer.

4. The magnetic tunnel junction device of claim 3, wherein the base seed layer comprises (001) textured magnesium oxide.

5. The magnetic tunnel junction device of claim 1, wherein the seed layer is a crystalline, non-magnetic chemical templating layer comprising CoAl.

6. The magnetic tunnel junction device of claim 1, wherein the ordered magnetic alloy is a Heusler alloy.

7. The magnetic tunnel junction device of claim 1, wherein the first free layer and the second free layer comprise at least one of Mn₃Ge, Mn₃Ga, Co₂MnSn, Mn₃Sn and Mn₃Sb.

8. The magnetic tunnel junction device of claim 1, wherein the first free layer and the second free layer each comprise a tensile strained Mn₃Ge layer.

9. The magnetic tunnel junction device of claim 1, wherein the first free layer has a thickness ranging from 20-100 Å, and the second free layer has a thickness ranging from 7-20 Å.

10. The magnetic tunnel junction device of claim 1, wherein the seed layer has a greater lattice constant than a lattice constant of the first free layer.

11. The magnetic tunnel junction device of claim 1, wherein the spacer layer is ordered alloy with a CsCl structure.

12. The magnetic tunnel junction device of claim 1, wherein the spacer layer is a crystalline, non-magnetic chemical templating layer comprising CoAl.

13. The magnetic tunnel junction device of claim 1, wherein the spacer layer has a greater lattice constant than the seed layer.

14. The magnetic tunnel junction device of claim 1, wherein the seed layer includes at least one of AlCo and AlNi and the spacer layer includes at least one of GaCo, AlRh, AlIr, of GaRh and GaIr.

15. The magnetic tunnel junction device of claim 1, wherein the tunnel barrier comprises magnesium oxide.

16. The magnetic tunnel junction device of claim 1, wherein the second free layer has a greater in-plane lattice constant than the first free layer.

17. A MRAM storage device comprising:
a magnetic tunnel junction device including
a seed layer; and
a free layer structure on the seed layer, the free layer structure comprising a first free layer, a spacer layer formed on the first free layer, and a second free layer formed on the spacer layer, wherein the first and second free layers each include an ordered magnetic alloy.

18. The MRAM storage device of claim 17, wherein the seed layer is a crystalline, non-magnetic chemical templating layer comprising CoAl.

19. The MRAM storage device of claim 17, wherein the ordered magnetic alloy is a Heusler alloy.

20. The MRAM storage device of claim 15, wherein the first free layer and the second free layer comprise at least one of Mn₃Ge, Mn₃Ga, Co₂MnSn, Mn₃Sn and Mn₃Sb.
